(19) United States
(12) Patent Application Publication
(10) Pub. No.: US 2022/0033964 A1
(43) Pub. Date: Feb. 3, 2022

(54) CHEMICAL VAPOR DEPOSITION PROCESS AND METHOD OF FORMING FILM

(71) Applicant: Winbond Electronics Corp., Taichung City (TW)

(72) Inventors: Pei-Yu Chen, Taichung City (TW); Wan-Yu Hung, Taichung City (TW)

(73) Assignee: Winbond Electronics Corp., Taichung City (TW)

(21) Appl. No.: 17/382,328

(22) Filed: Jul. 21, 2021

(30) Foreign Application Priority Data
Jul. 28, 2020 (TW) 109125348

(51) Int. Cl. C23C 16/44

(52) U.S. Cl. CPC C23C 16/4408

(57) ABSTRACT

A chemical vapor deposition process includes: performing a first-vapor deposition process to maintain a first temperature for a first time period; and performing a second-vapor deposition process, which includes: a temperature rising step, which makes the first temperature rise to a second temperature within a second time period; and a temperature dropping step, which makes the second temperature drop to a third temperature within a third time period.

### CROSS-REFERENCE TO RELATED APPLICATION

This application claims the priority benefit of Taiwan application serial no. 109125348, filed on Jul. 28, 2020. The entirety of the above-mentioned patent application is hereby incorporated by reference herein and made a part of this specification.

### TECHNICAL FIELD

The invention relates to a deposition method and a method of forming film, and more particularly, to a chemical vapor deposition process and a method of forming film.

### BACKGROUND

The chemical vapor deposition process is a film deposition method widely used in the semiconductor process. With the continuous miniaturization of component sizes, the control of a thickness of the film becomes more and more important. However, the current chemical vapor deposition process is prone to have the problem of uneven film thickness.

### SUMMARY

The invention provides a chemical vapor deposition process and a method of forming film, which can improve a film uniformity.

A chemical vapor deposition process according to an embodiment of the invention includes: performing a first-vapor deposition process to maintain a first temperature for a first time period; and performing a second-vapor deposition process, which includes: a temperature rising step, which makes the first temperature rise to a second temperature within a second time period; and a temperature dropping step, which makes the second temperature drop to a third temperature within a third time period.

A chemical vapor deposition process including a plurality of cycle processes is further provided according to an embodiment of the invention. Each of cycle processes includes: performing a first-vapor deposition process to maintain a first temperature for a first time period; and performing a second-vapor deposition process, which includes: a temperature rising step, which makes the first temperature rise to a second temperature within a second time period; and a temperature dropping step, which makes the second temperature drop to the first temperature within a third time period.

The chemical vapor deposition process and the method of forming film according to the embodiments of the invention can improve the film uniformity.

### BRIEF DESCRIPTION OF THE DRAWINGS

FIG. 1 is a temperature line chart at various stages of a chemical vapor deposition process according to a first embodiment of the invention.

FIG. 2 is a temperature line chart at various stages of a chemical vapor deposition process according to a second embodiment of the invention.

FIG. 3A and FIG. 3B are cross-sectional views of a manufacturing process of a film according to an embodiment of the invention.

### DETAILED DESCRIPTION

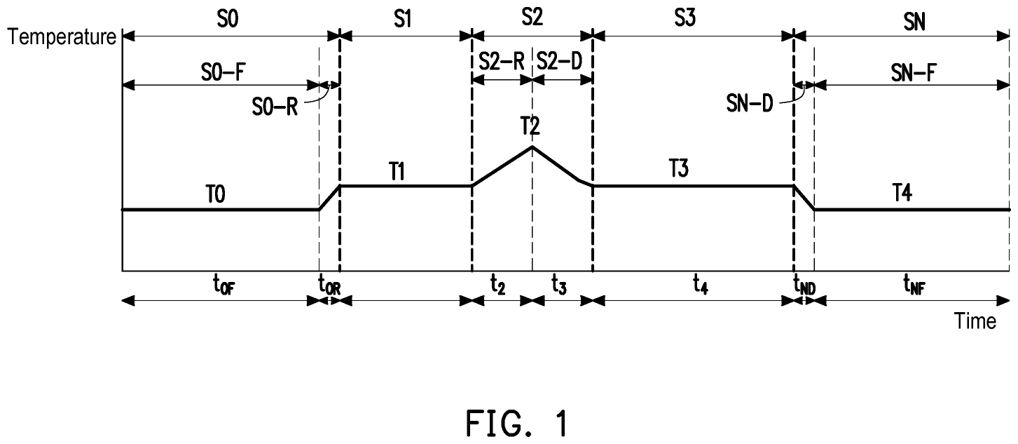

A chemical vapor deposition process of the invention is a deposition process of a film performed by a dynamic fine temperature control. In the first embodiment, the chemical vapor deposition process includes performing an initial stage S0, a first-vapor deposition process S1, a second-vapor deposition process S2, a purge stage S3 and a finishing stage SN, as shown in FIG. 1.

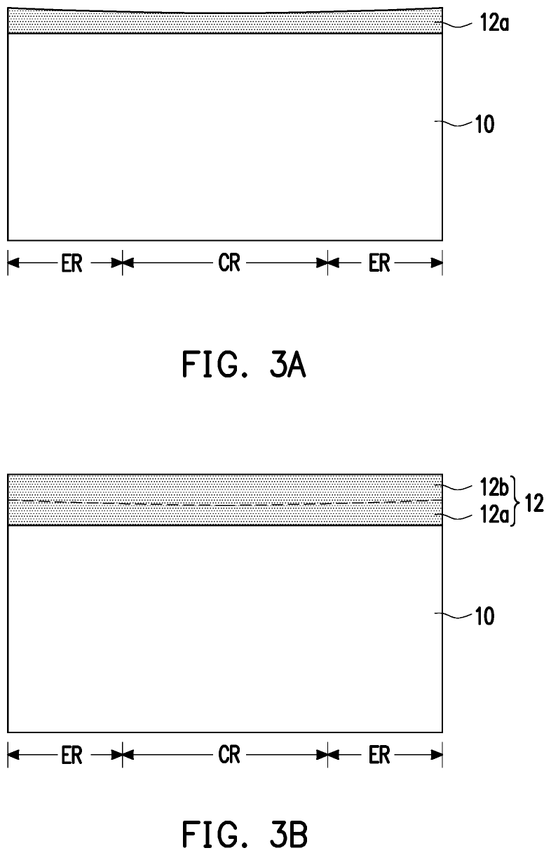

Referring to FIG. 1 and FIG. 3A, a substrate 10 in placed in a reaction chamber. Then, the initial stage S0 is performed. During the initial stage S0, a carrier gas is introduced into the reaction chamber but a reaction gas is not introduced into the reaction chamber, so that the film cannot be deposited on the substrate yet. The carrier gas may be an inert gas, such as nitrogen or helium. The initial stage S0 includes a temperature fixing step S0-F and a temperature rising step S0-R. The temperature fixing step S0-F maintains an initial temperature T₀ fixed at, for example, 300° C. to 650° C. for a time period t_{0F}, which is, for example, 5 minutes to 60 minutes. The temperature mentioned herein refers to the temperature of the reaction chamber. After the temperature fixing step S0-F is performed, the temperature rising step S0-R is then performed.

The temperature rising step S0-R makes the temperature rise from the initial temperature T₀ to a first temperature T₁ within a time period t_{0R}. The time period t_{0R} is, for example, 5 minutes to 10 minutes. The first temperature T₁ is, for example, 450° C. to 750° C. A difference between the first temperature T₁ and the initial temperature T₀ is, for example, 10° C. to 300° C. A heating rate of the temperature rising step S0-R is, for example, 0.03 to 0.35 degree/second. The temperature rising step S0-R makes the temperature rise from the initial temperature T₀ to the first temperature T₁ by, for example, a fixed heating rate or a stepwise heating rate.

Next, the first-vapor deposition process S1 is performed. During the first-vapor deposition process S1, the reaction gas is introduced into the reaction chamber to deposit the film on the substrate. In an embodiment, the film to be deposited is a silicon nitride film, and the reactive gas is, for example, silane and ammonia gas. During the first-vapor deposition process S1, the carrier gas can also be continuously introduced into the reaction chamber, and a deposition rate can be controlled by a flow rate of the carrier gas. The flow rate of the carrier gas may be less than or equal to the flow rate of the carrier gas introduced in the initial stage S0.

The first-vapor deposition process S1 maintains the first temperature T₁ for a first time period t₁. The first time period t₁ is, for example, 5 minutes to 25 minutes. The first time period t₁ is, for example, 20% to 70% of a total deposition time tₜₒₗ. Here, the total deposition time tₜₒₗ refers to a sum of the first time period t₁ and a second time period t₂ and a third time period t₃ mentioned later (tₜₒₗ=t₁+t₂+t₃). The total deposition time tₜₒₗ may also refer to a total time for introducing the reaction gas.

Referring to FIG. 1 and FIG. 3A, after the first-vapor deposition process S1 is performed, a thickness of a material layer 12a in an edge region ER of the substrate 10 will be slightly greater than the thickness of the material layer 12a in a central region CR of the substrate 10.

Then, the second-vapor deposition process S2 is performed. The second-vapor deposition process S2 includes a temperature rising step S2-R and a temperature dropping step S2-D. During the temperature rising step S2-R and the temperature dropping step S2-D, the reaction gas is continuously introduced into the reaction chamber, and the carrier gas can be selectively introduced, to continuously deposit the film on the substrate and increase the thickness of the film. The flow rate of the carrier gas may be less than or equal to the flow rate of the carrier gas introduced in the initial stage S0.

The temperature rising step S2-R of the second-vapor deposition process S2 makes the first temperature T₁ rise to a second temperature T₂ within a second time period t₂. The second time period t₂ is, for example, 3 minutes to 10 minutes. The second time period t₂ is, for example, less than or equal to the first time period t₁. The second time period t₂ is, for example, equal to or greater than the time period t_{0R} of the temperature rising step S0-R of the initial stage S0. The second time period t₂ is, for example, 5% to 40% of the total deposition time tₜₒₗ. A heating rate of the temperature rising step S2-R is, for example, 0.03 to 0.35 degree/second. The temperature rising step S2-R makes the temperature rise from the first temperature T₁ to the second temperature T₂ by, for example, a fixed heating rate or a multi-stage heating rate. The second temperature T₂ is, for example, 470° C. to 800° C. A difference between the second temperature T₂ and the first temperature T₁ is, for example, 20° C. to 50° C. The heating rate of the temperature rising step S2-R of the second-vapor deposition process S2 may be less than, equal to or greater than the heating rate of the temperature rising step S0-R of the initial stage S0.

Once the temperature rising step S2-R of the second-vapor deposition process S2 reaches the second temperature T₂, the temperature dropping step S2-D is performed immediately. The temperature dropping step S2-D makes the second temperature T₂ continuously drop down to a third temperature T₃ within a third time period t₃. Here, so-called “continuously drop” means that the temperature rising step is not included in the third time period t₃ so that the temperature continues to drop. The third time period t₃ is, for example, 5 minutes to 10 minutes. The third time period t₃ is, for example, less than or equal to the first time period t₁. The third time period t₃ may be less than, equal to or greater than the second time period t₂. The third time period t₃ is, for example, 5% to 70% of the total deposition time tₜₒₗ. A sum of the second time period t₂ and the third time period t₃ is, for example, 30% to 50% of the total deposition time tₜₒₗ. A cooling rate of the temperature dropping step S2-D is, for example, 0.03 to 0.2 degree/second. The temperature dropping step S2-D can make the temperature drop from the second temperature T₂ to the third temperature T₃ by, for example, a fixed cooling rate or a multi-stage cooling rate. The third temperature T₃ is, for example, 450° C. to 730° C. A difference between the third temperature T₃ and the second temperature T₂ is, for example, 20° C. to 50° C. A difference between the third temperature T₃ and the first temperature T₁ is, for example, 0° C. to 50° C. In an embodiment, the third temperature T₃ is equal to the first temperature T₁. The cooling rate of the temperature dropping step S2-D may be less than, equal to or greater than the heating rate of the temperature rising step S2-R. In an embodiment, the third time period t₃ of the temperature dropping step S2-D is greater than the second time period t₂, and the cooling rate of the temperature dropping step S2-D is less than the heating rate of the temperature rising step S2-R. In another embodiment, the third time period t₃ of the temperature dropping step S2-D is equal to the second time period t₂, and the cooling rate of the temperature dropping step S2-D is equal to the heating rate of the temperature rising step S2-R.

Referring to FIG. 1 and FIG. 3B, during the second-vapor deposition process S2, because the edge region ER of the substrate 10 is easier to response to changes in temperature instantly than the central region CR, after the temperature of the reaction chamber rises and drops, the deposition rate of the edge region ER of the substrate 10 is decreased significantly; because the central region CR of the substrate 10 responses to changes in temperature slowly, compared with the edge region ER, the deposition rate of the central region CR receives less impact. Therefore, during the second-vapor deposition process S2, a thickness of a material layer 12b deposited in the central region CR is greater than the thickness of the material layer 12b in the edge region ER. With this method, a film 12 finally formed can have a uniform thickness.

After the temperature dropping step S2-D is performed, the purge stage S3 is performed. During the purge stage S3, the reaction gas is stopped from being introduced into the reaction chamber, and yet the carrier gas is still continuously introduced to discharge the residual reaction gas in the reaction chamber and stop the film from being deposited on the substrate. The flow rate of the carrier gas introduced in the purge stage S3 may be greater than those of the carrier gas introduced in the first-vapor deposition process S1 and the second-vapor deposition process S2. A temperature of the purge stage S3 is equal to or less than a temperature of the temperature dropping step S2-D. The purge stage S3 maintains a minimum temperature of the temperature dropping step S2-D (i.e., the third temperature T₃) for a fourth time period t₄. The fourth time period t₄ is, for example, 1 minute to 60 minutes. The fourth time period t₄ is, for example, greater than or equal to the second time period t₂ and greater than or equal to the third time period t₃. The fourth time period t₄ may be less than, equal to or greater than the first time period t₁.

After the purge stage S3 is performed, the finishing stage SN is performed. The finishing stage SN includes a temperature dropping step SN_D and a temperature fixing step SN-F. During the temperature dropping step SN-D or the temperature fixing step SN-F of the finishing stage SN, the reaction gas and the carrier gas are no longer introduced into the reaction chamber, and thus the thickness of the film on the substrate will no longer be increased. The temperature dropping step SN-D makes the third temperature T₃ drop to a fourth temperature T₄ within a time period t_{ND}. The time period t_{ND} is, for example, 3 minutes to 10 minutes. The time period t_{ND} is, for example, less than or equal to the third time period t₃ for performing the temperature dropping step S2-D of the second-vapor deposition process S2. A cooling rate of the temperature dropping step SN-D is, for example, 0.03 to 0.35 degree/second. The temperature dropping step SN-D can make the temperature drop from the third temperature T₃ to the fourth temperature T₄ by, for example, a fixed cooling rate or a multi-stage cooling rate. The fourth temperature T₄ is, for example, 300° C. to 650° C. A difference between the fourth temperature T₄ and the initial temperature T₀ is, for example, 0° C. to 300° C. In an embodiment, the fourth temperature T₄ is equal to the initial temperature T₀. After the temperature dropping step SN-D is performed, the temperature fixing step SN-F is then performed. The temperature fixing step SN-F maintains the fourth temperature T₄ for a time period t_{NF}, which is, for example, 3 minutes to 10 minutes.

After the temperature fixing step SN-F of the finishing stage SN is performed, the substrate 10 is taken out of the reaction chamber. The film 12 formed on the substrate 10 has a favorable uniform thickness.

In another embodiment, a plurality of cycle processes can be included. Each of the cycle processes can include the aforementioned first-vapor deposition process S1 and the aforementioned second-vapor deposition process S2. After going through the cycle processes, the deposited film can have a more preferable uniformity.

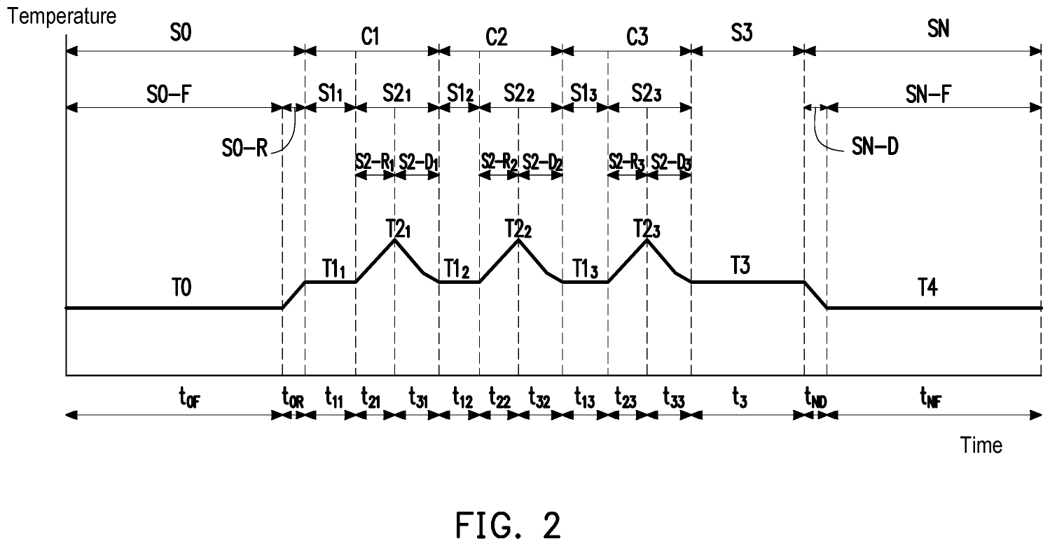

Referring to FIG. 2, in the second embodiment, a chemical vapor deposition process includes performing an initial stage S0, performing a plurality of cycle processes C1, C2 and C3, and performing a purge stage S3 and a finishing stage SN. Each of the cycle processes C1, C2 and C3 can include the first-vapor deposition process and the second-vapor deposition process described above. The initial stage S0 of the second embodiment is the same as the initial stage S0 described in the first embodiment, and will not be repeated here.

After the initial stage S0 is performed, the cycle processes (e.g., 1 to 50 cycle processes) are performed. Herein, three cycle processes C1, C2, and C3 are taken as examples, but not limited to thereto. The cycle processes C1, C2, and C3 include a first-vapor deposition process S1₁ and a second-vapor deposition process S2₁, a first-vapor deposition process S1₂ and a second-vapor deposition process S2₂, and a first-vapor deposition process S1₃ and a second-vapor deposition process S2₃, respectively. The first-vapor deposition processes S1₁, S1₂ and S1₃ of the second embodiment are similar to the first-vapor deposition process S1 of the first embodiment; the second-vapor deposition processes S2₁, S2₂ and S2₃ of the second embodiment are similar to the second-vapor deposition process S2 of the first embodiment, but differ in that the temperature dropping steps S2-D₁, S2-D₂ and S2-D₃ of the second-vapor deposition processes S2₁, S2₂ and S2₃ make second temperatures T2₁, T2₂ and T2₃ drop to T1₂, T1₃ and T₃, respectively.

In an embodiment, in the cycle processes C1, C2 and C3, the first temperatures T1₁, T1₂ and T1₃ are the same; the second temperatures T2₁, T2₂ and T2₃ are the same; and the third temperature T₃ is equal to the first temperatures T1₁, T1₂ and T1₃. In the cycle processes C1, C2 and C3, first time periods t₁₁, t₁₂ and t₁₃ may be the same or different; second time periods t₂₁, t₂₂ and t₂₃ may be the same or different; third time periods t₃₁, t₃₂ and t₃₃ may be the same or different. Heating rates of temperature rising steps S2-R₁, S2-R₂ and S2-R₃ of the second-vapor deposition processes S2₁, S2₂ and S2₃ of the cycle processes C1, C2 and C3 may be the same or different. Cooling rates of the temperature dropping steps S2-D₁, S2-D₂ and S2-D₃ of the second-vapor deposition processes S2 of the cycle processes C1, C2 and C3 may be the same or different. In an embodiment, the heating rates of the temperature rising steps S2-R₁, S2-R₂ and S2-R₃ may be the same, and the cooling rates of the temperature dropping steps S2-D₁, S2-D₂ and S2-D₃ may be the same.

After the cycle process C3 is performed, the purge stage S3 and the finishing stage SN are sequentially performed. The purge stage S3 and the finishing stage SN may be similar to the purge stage S3 and the finishing stage SN of the first embodiment described above. After the temperature fixing step SN-F of the finishing stage SN is performed, the substrate is taken out of the reaction chamber.

The method of the invention uses the dynamic fine temperature control to carry out the chemical vapor deposition process. As a result, various film layers including dielectric layers, metal layers or alloy layers can be deposited, and the formed film layers have a favorable uniformity.

1. A chemical vapor deposition process, comprising:
performing a first-vapor deposition process to maintain a first temperature for a first time period; and
performing a second-vapor deposition process, which comprises:
a temperature rising step, which makes the first temperature rise to a second temperature within a second time period; and
a temperature dropping step, which makes the second temperature drop to a third temperature within a third time period.

2. The chemical vapor deposition process of claim 1, wherein the second time period is 5% to 40% of a sum of the first time period, the second time period and the third time period.

3. The chemical vapor deposition process of claim 1, wherein the third time period is 5% to 70% of a sum of the first time period, the second time period and the third time period.

4. The chemical vapor deposition process of claim 1, wherein a heating rate of the temperature rising step is greater than or equal to a cooling rate of the temperature dropping step.

5. The chemical vapor deposition process of claim 1, wherein the second temperature is 20° C. to 50° C. higher than the first temperature, and the second temperature is 20° C. to 50° C. higher than the third temperature.

6. The chemical vapor deposition process of claim 1, wherein a difference between the first temperature and the third temperature is 0° C. to 50° C.

7. The chemical vapor deposition process of claim 1, further comprising:
performing an initial stage before performing the first-vapor deposition process, wherein the initial stage comprises a temperature fixing step, and a temperature difference between a temperature of the temperature fixing step and the first temperature is 0° C. to 300° C.

8. The chemical vapor deposition process of claim 1, further comprising:
performing a purge stage after performing the second-vapor deposition process, wherein a temperature of the purge stage is equal to the third temperature.

9. A chemical vapor deposition process comprising a plurality of cycle processes, each of the cycle processes comprising:
performing a first-vapor deposition process to maintain a first temperature for a first time period; and
performing a second-vapor deposition process, which comprises:
a temperature rising step, which makes the first temperature rise to a second temperature within a second time period; and
a temperature dropping step, which makes the second temperature drop to the first temperature within a third time period.

10. The chemical vapor deposition process of claim 9, wherein the plurality of cycle processes comprise 1 to 50 cycle processes.

11. The chemical vapor deposition process of claim 9, wherein the second time period of each of the cycle processes is 5% to 40% of a sum of the first time period, the second time period and the third time period of each of the cycle processes.

12. The chemical vapor deposition process of claim 9, wherein the third time period of each of the cycle processes is 5% to 70% of a sum of the first time period, the second time period and the third time period of each of the cycle processes.

13. The chemical vapor deposition process of claim 9, wherein a sum of the second time period and the third time period for performing each of the cycle processes is 30% to 50% of a sum of the first time period, the second time period and the third time period.

14. The chemical vapor deposition process of claim 9, wherein the second temperature is the same in each of the cycle processes, and the first temperature is the same in each of the cycle processes.

15. The chemical vapor deposition process of claim 9, wherein the second temperature is 20° C. to 50° C. higher than the first temperature.

16. The chemical vapor deposition process of claim 9, wherein a heating rate of the temperature rising step is greater than or equal to a cooling rate of the temperature dropping step.

17. The chemical vapor deposition process of claim 9, further comprising:
performing an initial stage before performing the first-vapor deposition process of a first cycle process, wherein the initial stage comprises a temperature fixing step, and a temperature difference between a temperature of the temperature fixing step and the first temperature is 0° C. to 300° C.

18. The chemical vapor deposition process of claim 9, further comprising:
performing a purge stage after performing the second-vapor deposition process of a last cycle process, wherein a temperature of the purge stage is equal to the third temperature.

19. A method of forming film, comprising:
depositing a film on a substrate by the chemical vapor deposition process of claim 1, wherein
when the first-vapor deposition process is performed, a thickness of a first material layer formed in an edge region of the substrate is greater than the thickness of the first material layer in a central region of the substrate;
when the second-vapor deposition process is performed, a thickness of a second material layer formed in the edge region of the substrate is less than the thickness of the second material layer in the central region of the substrate.
